(19) United States
(12) Patent Application Publication
(10) Pub. No.: US 2025/0279285 A1
(43) Pub. Date: Sep. 4, 2025

(54) Plasma Etching Method

(71) Applicants: IMEC VZW, Leuven (BE); Katholieke Universiteit Leuven, BE (BE)

(72) Inventors: Atefeh Fathzadeh, Heverlee (BE); Philippe Bezard, Leuven (BE)

(21) Appl. No.: 19/064,047

(22) Filed: Feb. 26, 2025

(30) Foreign Application Priority Data
Feb. 29, 2024 (EP) 24160637.5

(51) Int. Cl. H01L 21/3213; H01J 37/32

(52) U.S. Cl. CPC H01L 21/32136; H01J 37/32449; H01J 37/32935; H01J 2237/24585; H01J 2237/3341

(57) ABSTRACT

An example embodiment includes a method for dry etching a compound comprising at least two metals. The method includes injecting two or more reactants and a carrier gas into an etching chamber comprising the compound, wherein each of the metals can be etched by a plasma of at least one of said reactants. The method also include stopping the injection of at least one of the two or more reactants, and responsively causing a decrease of the concentration of at least one reactant of the two or more reactants. The method also includes igniting a plasma within the etching chamber for a time period such that the plasma is present during the decrease of the concentration.

### CROSS-REFERENCE TO RELATED APPLICATIONS

The present application is a non-provisional patent application claiming priority to European Patent Application No. 24160637.5, filed Feb. 29, 2024, the contents of which are hereby incorporated by reference.

### TECHNICAL FIELD

The present disclosure relates to the field of metal etching methods, including a method and system for dry etching compounds containing multiple metals.

### BACKGROUND

Plasma-based dry-etching is a critical technology in the semiconductor industry, enabling the precise patterning of materials for the fabrication of integrated circuits and other advanced electronic devices. The process involves the use of a plasma to generate chemically reactive species that can selectively remove material from a substrate, typically a semiconductor wafer. Plasmas are rich in electrons, which play a pivotal role in the dissociation of gas molecules into highly reactive radicals and the ionization of some of these molecules. These radicals are far more reactive than their stable molecular counterparts, making them effective for etching applications.

Dry etching relies on the formation of volatile products through the reaction of neutral molecules from the plasma with the surface atoms of the material being etched. An additional synergy in plasma-based dry-etching is the energetic ion bombardment of the surface, which breaks material bonds and mixes plasma and material atoms in an exchange layer that is typically a few nanometers thick.

Metal compounds, by their nature, include multiple metals, which can sometimes exhibit superior properties compared to their individual constituents. This is why there is a strong interest in using and patterning metal compounds. However, each metal of the compound reacts at a different rate with the incoming species, which can lead to dramatic slowdowns in the etching process or even complete blocking of further etching. This is depicted in FIGS. 1 to 4. The etching rate is typically limited by the component with the slowest reaction rate. For example, in a compound with elements A, B, and C (see FIG. 1), if element A is rapidly etched, it can leave behind a surface primarily composed of elements B and C (see FIG. 2). If element C does not form volatile products and must be sputtered away, it can accumulate on the wafer's surface, impeding the etching process (see FIG. 3).

In the case of compounds like InGaZnO where Ga can be etched with chlorine but not In (at low temperature), or MgₓZn₁₋ₓO, where zinc can be etched with chlorine, but MgO is insensitive to it, or NiAl, where nickel can be etched with CO, but aluminum cannot, the etching process becomes even more complex. The introduction of other gases can lead to deposition rather than etching (see FIG. 4), further complicating the process.

Despite some advancements in dry-etching technology, there remains a need for further improvements to address the challenges associated with etching compounds composed of multiple metals with different reaction rates.

### SUMMARY

The present disclosure is related to enabling better control on etching rates of compounds that include multiple metals. To this end, this disclosure includes a method and a system for dry etching a compound containing at least two metals.

This approach addresses the above-described problems in several ways. For instance, the presence of the stack of ferromagnetic and non-magnetic layers suppresses the skin effect at high frequencies. Additionally, the presence of the stack on the sidewalls of the first trench does not deteriorate the suppression of the skin effect in a largely applicable frequency range. The removal of the stack layers from the sidewalls is therefore not required during the production process of a component according to the invention. The conductors can also be produced by a damascene-type process that is compatible with current industrial processing environments.

One advantage of embodiments of the present disclosure that a method for dry etching a compound comprising at least two metals can be achieved, where the etching rates of the individual metals are independently controlled via a new lever. This permits for these etching rates to be closer to one another than would typically be achieved with classical plasma-based dry-etching. Alternatively, the method of the present disclosure can be used to tailor the post-etch composition of compound to one's needs. It is yet another advantage of embodiments of the present invention that the method can be applied to compounds of any crystallinity, i.e., that are amorphous or crystalline, making the invention applicable to a wide range of material types.

It is an advantage of embodiments of the present disclosure that the method can be used on compounds of any conductivity, from dielectric materials to superconductors. It is an advantage of embodiments of the present disclosure that the method can be used to form conductive elements of semiconductor devices, including metal interconnects for future nodes smaller than 2 nm, and can be applied to the patterning of various types of memories such as MRAM, FeRAM, RRAM, and devices used in quantum computing.

It is an advantage of embodiments of the present disclosure that it can help to prevent the formation of a blocking layer and maintains a high etch rate. It is a further advantage of embodiments of the present invention that the method allows for patterning of metal compounds layers.

In a first aspect, the disclosure describes a method for dry etching a compound comprising at least two metals. The method includes injecting two or more reactants and a carrier gas into an etching chamber comprising the compound, wherein each of the metals can be etched by a plasma of at least one of said reactants. The method also include stopping the injection of at least one of the two or more reactants, and responsively causing a decrease of the concentration of at least one reactant of the two or more reactants. The method also includes igniting a plasma within the etching chamber for a time period such that the plasma is present during the decrease of the concentration.

In a second aspect, the disclosure describes a system for dry etching a compound comprising at least two metals. The system includes an etching chamber configured to receive the compound, a gas delivery system configured to inject one or more reactants and a carrier gas into the etching chamber, a plasma generation system configured to ignite and maintain a plasma within the etching chamber, and a controller. The controller may be configured to control the gas delivery system to stop the injection of at least one of the one or more reactants, responsively causing the decrease of the concentration of at least one reactant of the one or more reactants. The controller may also be configured to ignite a plasma within the etching chamber for a time period such that the plasma is present during the decrease of the concentration of the at least one reactant.

In a third aspect, the disclosure describes a non-transitory computer-readable medium, storing program instructions that, when executed by one or more processors of a computing system, cause the one or more processors to perform (and/or cause) the operations of the first aspect.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

FIG. 1 illustrates a schematic representation of a three-element compound comprising at least two metals before exposure to a plasma, according to some approaches.

FIG. 2 illustrates a schematic representation of the initial stage of etching a compound with reactant exposure according to some approaches.

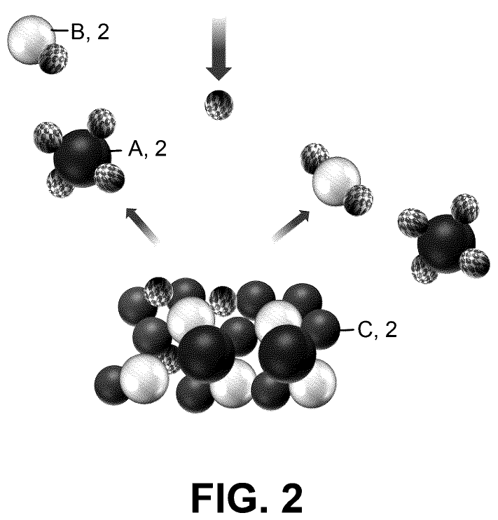

FIG. 3 illustrates a schematic representation of the etching process with one element predominantly removed, leaving a surface of mostly remaining elements and reactant according to some approaches.

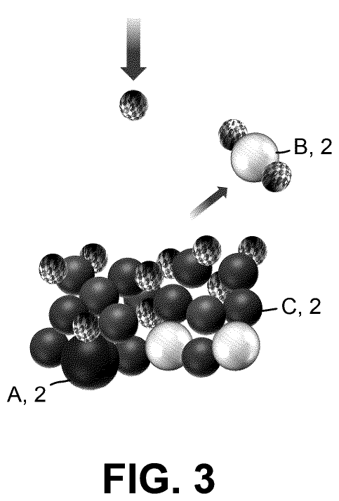

FIG. 4 illustrates a schematic representation of a worst-case scenario where deposition occurs on the modified compound surface during the etching process according to some approaches.

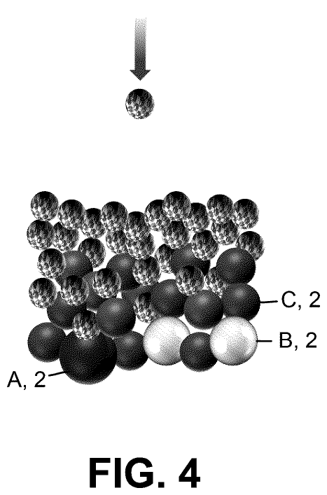

FIG. 5 illustrates a flow chart of an etching process according to example embodiments.

FIG. 6 illustrates a series of graphs plotting the gas concentration in the chamber as a function of process time according to example embodiments.

FIG. 7 is a schematic representation of a system for dry etching a compound according to example embodiments.

### DETAILED DESCRIPTION

The present disclosure will be described with respect to particular embodiments and with reference to certain drawings, but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of embodiments of the disclosure.

The terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein.

Moreover, the terms top and over and the like in the description and the claims are used for descriptive purposes and not necessarily for describing relative positions. It is to be understood that the terms so used are interchangeable under appropriate circumstances and that the embodiments of the disclosure described herein are capable of operation in other orientations than described or illustrated herein.

It is to be noticed that the term “comprising”, also used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be interpreted as being limited to devices consisting only of components A and B. It means that with respect to the present invention, the only relevant components of the device are A and B. The term “comprising” therefore covers the situation where only the stated features are present and the situation where these features and one or more other features are present. The word “comprising” according to the invention therefore also includes as one embodiment that no further components are present.

Similarly, it is to be noticed that the term “coupled” should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

Unless specifically specified, the description of a layer being present, deposited or produced “on” another layer or substrate, includes the options of the layer being present, produced or deposited directly on, i.e. in physical contact with, the other layer or substrate, and the layer being present, produced or deposited on one or a stack of intermediate layers between the layer and the other layer or substrate.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Furthermore, while some embodiments described herein include some, but not other features included in other embodiments, combinations of features of different embodiments are meant to be within the scope of the invention, and form different embodiments, as would be understood by those in the art. For example, in the following claims, any of the claimed embodiments can be used in any combination.

Furthermore, some of the embodiments are described herein as a method or combination of elements of a method that can be implemented by a processor of a computer system or by other means of carrying out the function. Thus, a processor with the necessary instructions for carrying out such a method or element of a method forms a means for carrying out the method or element of a method. Furthermore, an element described herein of an apparatus embodiment is an example of a means for carrying out the function performed by the element for the purpose of carrying out the invention.

In the description provided herein, numerous specific details are set forth. However, it is understood that embodiments of the invention may be practiced without these specific details. In other instances, well-known methods, structures and techniques have not been shown in detail in order not to obscure an understanding of this description.

As used herein and unless provided otherwise, when the etching rate of a metal in presence of its primary reactant is envisioned. This etching rate can be the etching rate in presence of only said primary reactant or, alternatively, the etching rate in presence of all reactants, including said primary reactant.

### I. EXAMPLE METHODS FOR DRY-ETCHING METAL COMPOUNDS

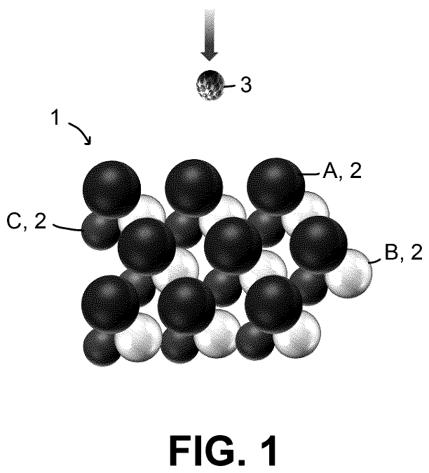

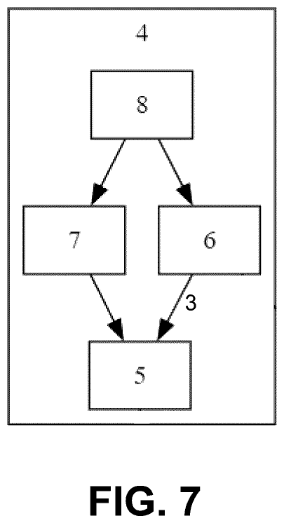

Aspects of the present invention relate to a method and system for dry etching a compound comprising at least two metals. The method may be applied for etching metal compounds in a controlled manner to fabricate semiconductor devices, including advanced memory technologies and quantum computing devices. This disclosure begins in reference to FIGS. 1 and 7 and the reference numbers therein.

In the first aspect, the present invention relates to a method for dry etching a compound (e.g., compound 1) comprising at least two metals (e.g., metals 2). The method may include the following steps:
injecting two or more reactants (e.g., reactants 3) and a carrier gas into an etching chamber (e.g., etching chamber 5) comprising the compound, wherein each of the metals can be etched by a plasma of at least one of said reactants
stopping the injection of at least one of the two or more reactants, and responsively causing a decrease of the concentration of at least one reactant of the two or more reactants, and
igniting a plasma within the etching chamber for a time period such that the plasma is present during the decrease of the concentration.

As used herein, and unless otherwise specified, the term “compound comprising at least two metals” refers to a material that comprises two or more distinct metallic elements, and eventually other non-metallic elements, chemically bonded together. This includes, but is not limited to, mixed metal oxides, mixed metal nitrides, mixed metal oxynitrides, mixed metal carbides (e.g., Max-phase materials), mixed metal oxycarbides, mixed metal carbonitrides, mixed metal oxycarbonitrides, metal alloys (e.g., high entropy alloys), intermetallic compounds, and metal matrix composites where the metallic elements are present in any proportion. Preferably the at least two metals represent together at least 50% of the compound, but may also represent at least 75%, at least 90%, or even 100% of the compound in some embodiments.

Each of the at least two metals forms, upon reaction with its primary reactant, an etch product having a boiling point below 600° C. In some embodiments, each of the at least two metals is selected from alkaline earth metals, transition metals, and post transition metals. Each of the at least two metals, in some embodiments, may not be gold, silver, palladium, or copper, as they can take very long to etch. Each of the at least two metals may be selected from, but not limited to, the list of Zn, Ga, In, Mg, Cr, Al, Mo, Ru, Ti, Ta, Zr, Hf, Sc, V, Nb, W, Co, Ni, and Sn. Specific embodiments of such compounds may include intermetallic compounds like NiAl and semiconducting metal oxides such as MgₓZn₁₋ₓO and IGZO (Indium Gallium Zinc Oxide). The number of metals in the compound is, in some embodiments, from 2 to 5. The number of chemical elements in the compound is, in some embodiments, from 2 to 5.

The compound can be present in any shape but in some embodiments is present as a layer of any thickness. The thickness of the compound, e.g., of the layer, may range in some embodiments from 0.1 nm to 1000 nm.

As used herein, and unless otherwise specified, the term “reactants” refers to chemical substances that are introduced into the etching chamber and are capable of reacting with the compound under plasma conditions. These reactants may be in gaseous form and can include, but are not limited to, H₂; CH₄; O₂; CO; CO₂; SO₂; CH₄; N₂; N₂O; NH₃; halogen-containing gases such as: Cl₂, Br₂, F₂, BCl₃, SF₆, SiF₄, NF₃, CₓF_{y} (e.g., CF₄ or C₄F₈), and CHₓF_{y} (e.g., CH₃F). The number of injected reactants may in some embodiments range from 1 to 8, and may range from 2 to 5 in some embodiments.

The one or more reactants (3) may be two or more reactants (3), allowing for more precise control over the etching process.

In embodiments, a method for dry etching a compound (e.g., compound 1) comprising at least two metals (e.g., metals 2) is presented. The method may include the following steps:
injecting two or more reactants (e.g., reactants 3) and a carrier gas into an etching chamber (e.g., etching chamber 5) comprising the compound, wherein each of the metals can be etched by a plasma of at least one of said reactants
stopping the injection of at least one of the two or more reactants, and responsively causing a decrease of the concentration of at least one reactant of the two or more reactants, and
igniting a plasma within the etching chamber for a time period such that the plasma is present during the decrease of the concentration.

In other words, the method may include an injecting step, a stopping step, and an igniting step.

In some embodiments, the stopping step may be determined based on the etching rates of each metal in the presence of its primary reactant when the plasma is ignited. For instance, the one or more reactants (3) may be two or more reactants (3), allowing for more precise control over the etching process. In some embodiments, the timing of the stopping step may be determined based on the etching rates of each metal in the presence of its primary reactant when the plasma is ignited, such that the primary reactant of the metal having the highest of said etching rates is stopped the earliest and the stopping time increases for primary reactants of metals having successively lower etching rates. This prioritizes the etching of metals based on their reactivities.

To determine which metal has the highest reactivity with a reactant, one or both of the experiments 1 and 2 (as described below) can, for instance, be performed. In embodiments where at least one of the reactant is the primary reactant for two or more metals, the timing of the stopping step for each of the other reactants may be set to be earlier than for at least one reactant being the primary reactant for two or more metals.

The timing of the stopping step for each of said other reactants may be determined based on the etching rates of each metal for which said other reactants are the primary reactants, when the plasma is ignited, such that the primary reactant of the metal having the highest of said etching rates is stopped the earliest and the stopping time increases for primary reactants of metals having successively lower said etching rates.

In some embodiments, the carrier gas may comprise one or more of Ar, He, Xe, N₂, and O₂. In some embodiments, the carrier gas may comprise one or more of Ar, He, and Xe, as they are not chemically reactive. In some embodiments, the carrier gas is not reactive toward the compound. If the carrier gas is also one of the reactant gases, the carrier gas may be the primary reactant responsible to etch the element with slowest etch rate in presence of its primary reactant. In some embodiments, the carrier gas is different from any of the reactants. In some embodiments, the carrier gas is more electropositive than any of the reactants.

As used herein, and unless otherwise specified, the term “etching chamber”, such as the etching chamber (5) in FIG. 7, refers to a sealed environment, typically within an etching system (4), where the etching process takes place. This chamber is designed to contain the compound (1) to be etched and to allow for the controlled introduction of reactants (3), carrier gases, and the generation of plasma. The etching chamber may include various components such as gas inlets, exhaust systems, and electrodes for plasma generation. It is typically constructed from materials that are resistant to the corrosive effects of the etching process.

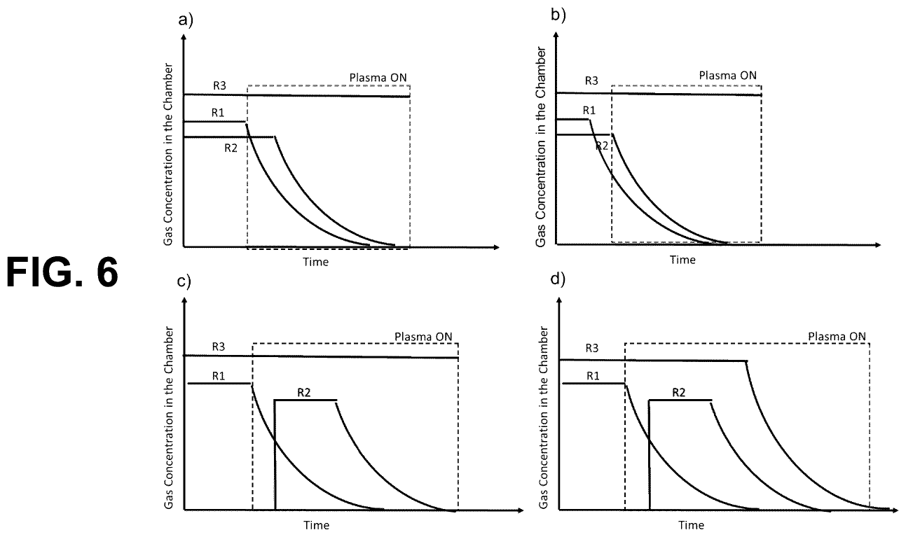

During the method described above, the injection of at least one of the reactants (3) is stopped. This is visible in each of the embodiments depicted in FIG. 6. In some embodiments, two or more reactants are injected in the injecting step and the injection of at least two of these reactants is stopped in the stopping step. In other words, the stopping step may involve stopping the injection of at least two of the reactants (3), thereby causing the decrease of each of the concentrations of said at least two of the reactants (3), and wherein the igniting step may involve igniting the plasma within the etching chamber (5) for a time period such that the plasma is present during the decreases. This is also what is depicted in all embodiments of FIG. 6. In some embodiments, when more than one reactant is stopped the stopping step, they are not stopped simultaneously. In some embodiments, all of the reactants injected in the injecting step are stopped in the stopping step. This is depicted in chart d) in FIG. 6. In other embodiments, all but one of the reactants injected, are stopped. This is depicted in charts a), b), and c) in FIG. 6.

In a plasma etching system, a vacuum pump may be used to maintain the low pressure required for plasma generation. Once the injection of a reactant is stopped, the existing molecules of the reactant in the chamber are gradually removed by the vacuum system, which causes the decrease in concentration.

In the igniting step, the plasma is ignited. As used herein, and unless otherwise specified, the term “igniting a plasma” refers to the process of initiating a plasma state within the etching chamber (5) by applying energy to the gas mixture containing the reactants (3) and carrier gas. This energy can be supplied through various means such as radio frequency (RF) power, microwave power, or direct current (DC) discharge. The plasma consists of a collection of particles including electrons, ions, and neutral species that are capable of interacting with the compound (1) to effect etching.

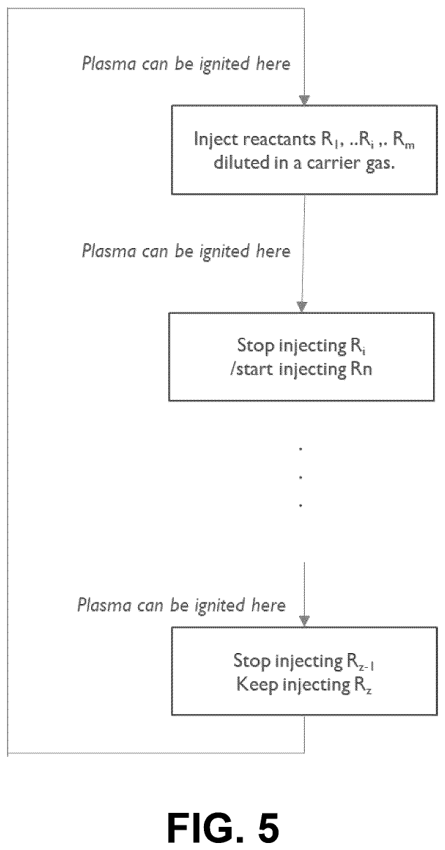

The plasma may be ignited for a time period such that the plasma is present during the decrease of the concentration of at least one reactant. In some embodiments, the plasma is ignited for a time period such that the plasma is present during the decrease of the concentration of all reactants which injections have been stopped. This is depicted in FIG. 6. In some situations, it is not necessary for the plasma to be on, i.e., ignited, during the whole decrease of at least one reactant. It is sometimes sufficient if the plasma is ignited for at least part of the decrease of at least one reactant (3). In some embodiments, the plasma is present during the entire decrease of the concentration of at least one reactant (3). The plasma is typically ignited before or simultaneously with the stopping of the injection of at least a reactant (3), as depicted in all embodiments of FIG. 6. However, it can also be ignited after the stopping occurred. FIG. 5 shows times where the ignition of the plasma can be started in embodiments of the first aspect. As shown, the plasma can be started at any time as long as it is present during the decrease of a reactant (3).

In some embodiments, the igniting step may involve igniting a plasma within the etching chamber (5) for a time period such that the plasma is present during said decrease, thereby simultaneously controlling the etching rates of the at least two metals (2).

In some embodiments, the igniting step may involve: igniting a plasma within the etching chamber (5) for a time period such that the plasma is present and the dry etching proceeds during said decrease.

As used herein, and unless otherwise specified, the term “time window extending from 500 ms before and 500 ms after” refers to a specific period during which the ignition of the plasma is initiated relative to the stopping of the injection of one of the reactants (3). This time window defines a range of acceptable timings for starting the plasma ignition, where “500 ms before” indicates that the plasma can be ignited up to half a second before the reactant injection is stopped, and “500 ms after” indicates that the plasma can be ignited up to half a second after the reactant injection has ceased. Some embodiments may specify narrower time windows, such as from 250 ms before and after, or from 100 ms before and after. For instance, the injection can be stopped at the same time as the ignition of the plasma is started. Stopping the injection of one of the reactants approximatively at the same as when the plasma is started frequently may provide different results. However, reactants can also be stopped before or after, even longer than 500 ms before or after, in some embodiments.

In some embodiments, the gas injection of each reactant (3) is maintained for a period of at least 10 ms, though this period may be at least 50 ms, or even at least 100 ms in some embodiments. Longer gas injection times can be more reproducible, which can lead to better control of the etching process.

The magnitude of the flow rates of the two or more reactants (3) during their injection period may be determined based on the etching rates of each metal (2) in the presence of the reactant (3) most responsible for its etching rate when the plasma is ignited, e.g., in the presence of said two or more reactants (3) when the plasma is on. In embodiments where at least one of the reactant is the primary reactant for two or more metals, the flow rate of each of the other reactants during their injection period may be set to be lower than for the at least one reactant being the primary reactant for two or more metals. The relative magnitude of the flow rates of each of said other reactants during their injection period may be determined based on the etching rates of each metal for which said other reactants are the primary reactants, when the plasma is ignited, such that the primary reactant of the metal having the highest of said etching rate is injected at the lowest flow rate, and the flow rates increase for primary reactants of metals having successively lower etching rates.

Each reactant (3) for which injection is stopped in the stopping step may be injected at a gas flow of from 0.1 sccm to 1500 sccm, with other ranges provided for more precise control in some embodiments. As used herein, and unless otherwise specified, the term “gas flow of from 0.1 sccm to 1500 sccm” specifies the range of flow rates at which the reactants (3) are introduced into the etching chamber (5). The unit “sccm” stands for standard cubic centimeters per minute and is a measure of the volumetric flow rate of a gas, standardized to a set of reference conditions of temperature and pressure. Some embodiments specify narrower ranges such as from 0.5 sccm to 500 sccm, from 1 sccm to 200 sccm, or from 2 sccm to 50 sccm. A gas flow of from 0.1 to 50 sccm may be useful for most reactants (3).

In some embodiments, a primary reactant (3) of the metal (2) having the lowest etching rate in presence of its primary reactant (3) when the plasma is ignited may be injected without interruption, i.e., without a stopping step. This may be useful if that lowest etching rate is at least twice smaller, such as at least four times smaller, than the etching rate of the metal having the second lowest etching rate in presence of its primary reactant (3) when the plasma is ignited. In some embodiments, the primary reactant of the metal having the lowest etching rate may be injected without interruption at a gas flow of from 100 to 1500 sccm if that etching rate is at least two times, such as at least four times smaller than the etching rate of the metal having the second lowest etching rate in presence of its primary reactant when the plasma is ignited. In some embodiments, where a reactant is the primary reactant for two or more metals, this reactant may be injected without interruption at a higher flow rate than the other reactants.

The method may also involve a step, before the injecting step. This step may involve determining the relative etching rates of each metal (2) in the presence of the reactant (3) most responsible for its etching rate, e.g., in the presence of said two or more reactants (3), when the plasma is ignited. Embodiments including this step provide the advantage of enabling a more informed approach to the etching process by better understanding the etching rates beforehand, which could lead to better results.

In some embodiments, the compound may be amorphous. Although the present disclosure may be applied to all kinds of structures, including crystalline structures, amorphous compounds can be advantageous in some situations, especially when the thickness of the material layer is relatively low, such as less than 10 nm. However, because the method may be plasma-based, the method may nevertheless inflict minor damage, amounting to a few angstroms or nanometers, to the crystalline lattice of materials. This becomes more problematic when dealing with crystalline material layers that are only a few nanometers thick. In some embodiments, the compound may form a layer which is at least 10 nm thick and is crystalline.

In some embodiments, the compound may form a conductive element of a semiconductor device, such as a metal interconnect, or be part of memory devices, or quantum computing devices. As used herein, and unless otherwise specified, the term “conductive element of a semiconductor device” refers to a component within a semiconductor device that is designed to conduct electrical current. This includes, but is not limited to, metal interconnects, electrodes, gates, and contact pads. These conductive elements can be made from various conductive materials, including metals and metal alloys, and are integral to the functionality of semiconductor devices such as transistors, diodes, and integrated circuits.

As used herein, and unless otherwise specified, the term “Metal (2) interconnect” refers to a conductive pathway within a semiconductor device that electrically connects different components or regions of the device. These interconnects are typically made of metals or metal alloys and are used to establish electrical continuity within the device. The term “<2 nm node” refers to semiconductor technology nodes with feature sizes smaller than 2 nanometers, indicating advanced semiconductor manufacturing processes that produce devices with extremely fine geometries.

As used herein, and unless otherwise specified, the term “Memory” encompasses various types of data storage technologies used in semiconductor devices, including but not limited to Magnetoresistive Random-Access Memory (MRAM), Ferroelectric RAM (FeRAM), Resistive RAM (RRAM), and spin-torque memory devices. The term “quantum computing device” refers to a computing system that utilizes the principles of quantum mechanics, such as superposition and entanglement, to perform operations on data.

The conductive element may also be a superconductor. As used herein, and unless otherwise specified, the term “superconductor” refers to a material that can conduct electricity without resistance below a certain critical temperature. Superconductors are used in various applications, including conductive elements in semiconductor devices, where they enable highly efficient electrical conduction. Non-limiting examples of compounds (1) are MgₓZn₁₋ₓO, IGZO, or NiAl. The compound is not necessarily a conductor and could be a semiconductor compound, such as IGZO, or be a dielectric.

The etching process may be conducted in cycles, with each cycle comprising the injecting, stopping, and/or igniting steps, and, for instance, each cycle may remove less than 1 nm of the compound (1). This enables precise material removal with minimal etching per cycle. As used herein, and unless otherwise specified, the term “each cycle removes less than 1 nm of the compound (1)” indicates that the amount of material etched away from the compound (1) during a single cycle of the etching process is less than one nanometer in thickness. This level of control allows for very fine adjustments to the etched features, which m advantageous in advanced semiconductor manufacturing where feature sizes can be on the order of nanometers.

In embodiments, the method may be for patterning the compound (1). As used herein, and unless otherwise specified, the term “patterning the compound (1)” refers to the process of creating a specific geometric pattern on the surface of the compound (1) by selectively removing material through etching.

In some embodiments, a system may be included. The system (e.g., system 4) for dry etching a compound (e.g., compound 1) may include an etching chamber (e.g., etching chamber 5), a gas delivery system (e.g., gas delivery system 6), a plasma generation system (e.g., plasma generation system 7), and a controller (e.g., controller 8). The controller may be configured to control the gas delivery system to stop the injection of at least one of the one or more reactants, responsively causing the decrease of the concentration of at least one reactant of the one or more reactants. The controller may also be configured to ignite a plasma within the etching chamber for a time period such that the plasma is present during the decrease of the concentration of the at least one reactant.

As used herein, and unless otherwise specified, the system described above may refer to an apparatus or setup designed to perform the process of dry etching on a compound (1) comprising at least two metals (2). This system includes various components such as an etching chamber (5), gas delivery system (6), plasma generation system (7), and a controller (8) that work together to facilitate the etching process. FIG. 7 provides a schematic representation of the system (4), showing the components and their arrangement within the etching system.

The system (4) may be configured to execute the steps of the method according to any embodiments of the first aspect, thereby enabling the system (4) to perform the method with precision and repeatability.

In some embodiments, a non-transitory computer-readable medium may be included. Such a medium may contain instructions which, when executed by a computer or a controller (8), cause the system (4) to perform specific operations. This product can, for instance, be distributed on a physical medium like a CD-ROM or as a digital download.

### II. EXAMPLE IMPLEMENTATIONS FOR DRY-ETCHING METAL COMPOUNDS

In this section, an example implementation of the above processes and/or systems is provided, involving composition-consistent etching of a metal compound.

In some approaches, the etching of metal compounds is typically not uniform, with some elements etching faster than others. The present disclosure provides an etching method that allows to reduce this tendency, or even to eliminate it.

In this non-limiting example, one way to implement the method will be illustrated, assuming that no foreknowledge of the etching rates of the various components of a metal compound is available. The example considers an alloy with components (A, B, C), each of them with different requirements (chemical reactant, ion assistance, etc.) to be etched. R1, R2 and R3 are the reactants injected to etch each component of the alloy. For clarity and simplicity, it is assumed that R1 is mostly responsible for etching of A, R2 for B and R3 for C. In other words, R1, R2, and R3 are the primary reactants for A, B, and C respectively.

A difficulty may arise from the fact that different metals of the metal compound will have different needs in terms of neutral species and in terms of ions to achieve an optimal etching speed.

Different etch requirements for each compound are summarized in the following table:

| | | | | | Corresponding |
|---|---|---|---|---|---|
| Neutral | Corresponding gas | Ion | Corresponding | Neutral/Ion | graph/injection |
| needs | flow | needs | plasma time | ratio | scenario |
| High | Gas injection with | High | Long | Medium | R3 in graphs |
| | plasma ON | Medium | Medium | High | a, b, c |
| | | Low | Short | Very high | |
| Medium | Short gas injection | High | Long | Low | R2 in graphs |
| | with plasma ON | Medium | Medium | Medium | a, c, d |
| | | Low | Short | High | R3 in graph d |
| Low | Reduce gas | High | Long | Very low | R1 in all graphs |
| | concentration while | Medium | Medium | Low | R2 in graph b |
| | plasma is ON | Low | Short | Medium | |

The neutral/ion flux ratio, and thereby the relative etching rates of each metal, can be controlled by letting the concentrations of one or more reactants decay in the plasma phase. During one decay, the flux of neutrals decreases after the injection of the gas has been stopped as they are either being consumed by reactions or being pumped out. The timing of this stopping with respect to the ignition period of the plasma will, therefore, determine the etching that will be achieved during that cycle for a metal for which the reactant stopped is the primary reactant. Hence, by having the plasma remaining ignited during a period of reactant decay, one has at its disposition a control lever for adapting the etching rate of A, B, and C. Hence, in some embodiments, the igniting step may involve Igniting a plasma within the etching chamber (5) for a time period such that the plasma is present during the decrease, thereby simultaneously controlling the etching rates of the at least two metals (2).

One use of this control lever is for achieving a more equal etching rate for A, B, and C than would otherwise be possible. It is this use that this example focuses on. Other uses can, of course, also be envisioned.

For the present example, it is assumed that the carrier gas is more electropositive than R1, R2, and R3. As the neutral flux decreases, the ion flux will increases. In the aforementioned scenario, the etching rates of A, B, and C can be brought closer to equality by taking into account the following: (1) when a low neutral/ion ratio is preferred, the injection of the corresponding gas is preferably stopped before (or simultaneously with) the plasma ignition; (2) when a high neutral/ion ratio is preferred, the corresponding gas injection is preferably sustained all along the plasma step (or stopped slightly before the end); (3) when a moderate neutral/ion ratio is preferred, injection can be sustained for as much time as needed during the plasma step to ensure the need for reactive neutrals before the concentration decays and the remaining plasma time ensures the needs for energetic ions. If both needs are low, then the gas injection could start during the plasma step, thereby shortening the injection of neutrals and the ion bombardment of a surface saturated with reactants.

To accommodate excessive reactivity of a reactant with one component of the alloy, very short pulses could be injected at low concentrations as illustrated by R1 in graph b) of FIG. 6.

The four graphs of FIG. 6 represent four scenarios.

To establish under which scenario of the four scenarios shown in FIG. 6 a particular process could fall, the following approach can, as an illustrative example, be applied.

Experiment 1: Define respective etch rates. In this example, it is assumed that the respective etch rates of A, B, and C in presence of respectively R1, R2, and R3 are not known. This is a worst case scenario. To determine the respective etch rates, one can proceed as follows:
Inject one reactant at an arbitrary flow rate (though it is recommend keeping it in the low range such as 2-50 sccm, to limit the movements of the pressure-regulating valve),
Strike the plasma at the same time as the injection is being stopped (as an example), and
Keep the plasma ON for an arbitrary amount of time (e.g., 3 seconds).

By measuring the composition of the alloy pre- and post-etching, one can see how much the proportion of each component evolved (accumulation of some elements, depletion of others). This allows to determine the etching of what metal that reactant is most responsible for. It also gives an indication of the etching rate of each metal in presence of that reactant.

This experiment may then be repeated for each reactant.

Experiment 2: Refine respective etch rates. To have a more precise idea of the relative etching rates of A, B, and C during an etching period where all three reactants are present, the following experiment can be performed.
Inject all three reactants at the same time and at the same arbitrary flow rate (e.g., in the range 2-50 sccm),
Strike the plasma at the same time as the injection is being stopped (as an example) for all three reactants,
Keep the plasma ON for an arbitrary amount of time (e.g., 3 seconds).

By measuring the composition of the alloy pre- and post-etching, one can see how much the proportion of each component evolved (accumulation of some elements, depletion of others).

Experiment 3: Dependency of etch rates with neutral and ion fluxes. This experiment can be performed to gain a more in-depth understanding of how neutral-sensitive a metal is. Indeed, the more the etching rate of a metal is neutral sensitive, the more an increase in the pressure will increase its etching rate.

For this experiment, one can run the same experiments as above at a larger pressure (e.g. 20-40 mTorr), without changing the gas flows or power settings, then measure the composition of the alloy post-etching to refine the desired range of pressure for this process.

Experiment 4: Interactions between gases in plasma step. Further experiments can be performed to explore how the presence of multiple reactants influence etching during the plasma step. For instance, a gas injection scheme similar to graph c) or d) in FIG. 6 can be performed to ensure that at least two gases are present in the reactor at the same time. The composition can then be measured post-etching.

Experiment 5: Definition of gas concentration and injection stops. To maintain a same composition as much as possible during etching, the slowest elements to etch may have their corresponding reactant flow set high compared to the others. Furthermore, their injection may be sustained longer than the others (again, more gas needed to reach an etch rate equivalent to the one of the other elements). Following this logic and the results of the previous experiments in terms of composition and etch rate results, gas injection timings and relative concentrations can be adjusted.

Depending on prior knowledge of the behaviors of A, B, and C in presence of R1, R2, and R3, a combination of one or more of the above experiments will help selecting the most relevant of the scenarios depicted in FIG. 6 for performing an etching process. As noted before, these scenarios are merely given as examples—other etching processes and scenarios are possible in other embodiments.

Experiment 6: Impact of ion fluence on composition of the alloy. For this experiment, a longer plasma duration (5 to 10 seconds instead of the initial 3 seconds, for instance) can be used in the chosen scenario to assess if more ions are needed for a certain element or not.

In some embodiments, the process may involve keeping the gas flows of each reactant low compared to the carrier gas flow. Indeed, the total gas flow may not be conserved in this process when the injection stops, resulting in movement of the pressure-regulating valve (closing more). The same valve would also have to move (opening more) at plasma ignition as the density of species (and thus global pressure) increases at this moment (molecules are dissociated into several fragments). By keeping the injected gas flows low relative to the carrier gas flow, these moves can be minimized and even compensated with dedicated optimizations. Going for large reactant gas flows would result in large moves of the valve and reproducibility of the results would suffer. Delays of injection would be the most adequate parameter to use to set the relative concentrations of these gases if large flow ratios would be used.

### III. ENUMERATED EXAMPLE EMBODIMENTS

Embodiments of the present disclosure may thus relate to one of the enumerated example embodiments (EEEs) listed below.

EEE 1 is a method for dry etching a compound comprising at least two metals, the method comprising:
injecting two or more reactants and a carrier gas into an etching chamber comprising the compound, wherein each of the metals can be etched by a plasma of at least one of said reactants,
stopping the injection of at least one of the two or more reactants, and responsively causing a decrease of the concentration of at least one reactant of the two or more reactants, and
igniting a plasma within the etching chamber for a time period such that the plasma is present during the decrease of the concentration.

EEE 2 is the method according to EEE 1, wherein the carrier gas is different from any of the reactants and is not reactive toward the compound.

EEE 3 is the method according to EEE 1, wherein the carrier gas is one of the two or more reactants and is the primary reactant responsible to etch the element of the compound with the slowest etch rate in presence of its primary reactant.

EEE 4 is the method according to EEE 1, wherein stopping the injection of at least one of the two or more reactants comprises stopping the injection of at least two of the reactants, responsively causing the decrease of each of the concentrations of the at least two of the reactants, and wherein igniting a plasma within the etching chamber comprises igniting the plasma within the etching chamber for a time period such that the plasma is present during each of the decreases of the concentrations.

EEE 5 is the method according to EEE 1, wherein the ignition of the plasma is started within a time window extending from 500 ms before and 500 ms after the stopping of the injection of one of the reactants.

EEE 6 is the method according to EEE 1, wherein the timing of stopping the injection of at least one of the two or more reactants is determined based on the etching rates of each metal in the presence of its primary reactant when the plasma is ignited.

EEE 7 is the method according to EEE 6, further comprising determining the relative etching rates of each metal in the presence of the reactant most responsible for its etching rate when the plasma is ignited.

EEE 8 is the method according to EEE 1, wherein the magnitude of the flow rates of the two or more reactants during their injection period is determined based on the etching rates of each metal in the presence of the reactant most responsible for its etching rate when the plasma is ignited.

EEE 9 is the method according to EEE 1, wherein each reactant for which injection is stopped is injected at a gas flow of 0.1 sccm to 1500 sccm.

EEE 10 is the method according to EEE 1, wherein the compound is amorphous.

EEE 11 is the method according to EEE 1, wherein the compound forms a layer which is at least 10 nm thick and is crystalline.

EEE 12 is the method according to EEE 1, wherein the compound forms a conductive element of a semiconductor device.

EEE 13 is the method according to EEE 1, wherein the etching process is conducted in cycles.

EEE 14 is the method of EEE 1, wherein the carrier gas comprises one or more of Ar, He, Xe, N₂, and O₂.

EEE 15 is a system for dry etching a compound comprising at least two metals, the system comprising:
an etching chamber configured to receive the compound;
a gas delivery system configured to inject one or more reactants and a carrier gas into the etching chamber;
a plasma generation system configured to ignite and maintain a plasma within the etching chamber; and
a controller configured to:
   control the gas delivery system to stop the injection of at least one of the one or more reactants, responsively causing the decrease of the concentration of at least one reactant of the one or more reactants; and
   ignite a plasma within the etching chamber for a time period such that the plasma is present during the decrease of the concentration of the at least one reactant.

EEE 16 is the system according to EEE 15, wherein the carrier gas is different from any of the reactants and is not reactive toward the compound.

EEE 17 is the system according to EEE 15, wherein the carrier gas is one of the two or more reactants and is the primary reactant responsible to etch the element of the compound with the slowest etch rate in presence of its primary reactant.

EEE 18 is a non-transitory computer-readable medium, storing program instructions that, when executed by one or more processors of a computing system, cause the one or more processors to perform operations for dry etching a compound comprising at least two metals comprising:
injecting two or more reactants and a carrier gas into an etching chamber comprising the compound, wherein each of the metals can be etched by a plasma of at least one of said reactants,
stopping the injection of at least one of the two or more reactants, and responsively causing a decrease of the concentration of at least one reactant of the two or more reactants, and
igniting a plasma within the etching chamber for a time period such that the plasma is present during the decrease of the concentration.

EEE 19 is the non-transitory computer-readable medium according to EEE 18, wherein the carrier gas is different from any of the reactants and is not reactive toward the compound.

EEE 20 is the non-transitory computer-readable medium according to EEE 18, wherein the carrier gas is one of the two or more reactants and is the primary reactant responsible to etch the element of the compound with the slowest etch rate in presence of its primary reactant.

### IV. CONCLUSION

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, operation, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step, block, or operation that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical operations or actions in the method or technique. The program code and/or related data can be stored on any type of computer-readable medium such as a storage device including RAM, a disk drive, a solid state drive, or another storage medium.

The computer-readable medium can also include non-transitory computer-readable media such as computer-readable media that store data for short periods of time like register memory and processor cache. The computer-readable media can further include non-transitory computer-readable media that store program code and/or data for longer periods of time. Thus, the computer-readable media may include secondary or persistent long term storage, like ROM, optical or magnetic disks, solid state drives, compact-disc read only memory (CD-ROM), for example. The computer-readable media can also be any other volatile or non-volatile storage systems. A computer-readable medium can be considered a computer-readable storage medium, for example, or a tangible storage device.

Moreover, a step, block, or operation that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed is:

1. A method for dry etching a compound comprising at least two metals, the method comprising:
injecting two or more reactants and a carrier gas into an etching chamber comprising the compound, wherein each of the metals can be etched by a plasma of at least one of said reactants,
stopping the injection of at least one of the two or more reactants, and responsively causing a decrease of the concentration of at least one reactant of the two or more reactants, and
igniting a plasma within the etching chamber for a time period such that the plasma is present during the decrease of the concentration.

2. The method according to claim 1, wherein the carrier gas is different from any of the reactants and is not reactive toward the compound.

3. The method according to claim 1, wherein the carrier gas is one of the two or more reactants and is the primary reactant responsible to etch the element of the compound with the slowest etch rate in presence of its primary reactant.

4. The method according to claim 1, wherein stopping the injection of at least one of the two or more reactants comprises stopping the injection of at least two of the reactants, responsively causing the decrease of each of the concentrations of the at least two of the reactants, and wherein igniting a plasma within the etching chamber comprises igniting the plasma within the etching chamber for a time period such that the plasma is present during each of the decreases of the concentrations.

5. The method according to claim 1, wherein the ignition of the plasma is started within a time window extending from 500 ms before and 500 ms after the stopping of the injection of one of the reactants.

6. The method according to claim 1, wherein the timing of stopping the injection of at least one of the two or more reactants is determined based on the etching rates of each metal in the presence of its primary reactant when the plasma is ignited.

7. The method according to claim 6, further comprising determining the relative etching rates of each metal in the presence of the reactant most responsible for its etching rate when the plasma is ignited.

8. The method according to claim 1, wherein the magnitude of the flow rates of the two or more reactants during their injection period is determined based on the etching rates of each metal in the presence of the reactant most responsible for its etching rate when the plasma is ignited.

9. The method according to claim 1, wherein each reactant for which injection is stopped is injected at a gas flow of 0.1 sccm to 1500 sccm.

10. The method according to claim 1, wherein the compound is amorphous.

11. The method according to claim 1, wherein the compound forms a layer which is at least 10 nm thick and is crystalline.

12. The method according to claim 1, wherein the compound forms a conductive element of a semiconductor device.

13. The method according to claim 1, wherein the etching process is conducted in cycles.

14. The method of claim 1, wherein the carrier gas comprises one or more of Ar, He, Xe, N₂, and O₂.

15. A system for dry etching a compound comprising at least two metals, the system comprising:
an etching chamber configured to receive the compound;
a gas delivery system configured to inject one or more reactants and a carrier gas into the etching chamber;
a plasma generation system configured to ignite and maintain a plasma within the etching chamber; and
a controller configured to:
control the gas delivery system to stop the injection of at least one of the one or more reactants, responsively causing the decrease of the concentration of at least one reactant of the one or more reactants; and
ignite a plasma within the etching chamber for a time period such that the plasma is present during the decrease of the concentration of the at least one reactant.

16. The system according to claim 15, wherein the carrier gas is different from any of the reactants and is not reactive toward the compound.

17. The system according to claim 15, wherein the carrier gas is one of the two or more reactants and is the primary reactant responsible to etch the element of the compound with the slowest etch rate in presence of its primary reactant.

18. A non-transitory computer-readable medium, storing program instructions that, when executed by one or more processors of a computing system, cause the one or more processors to perform operations for dry etching a compound comprising at least two metals comprising:
injecting two or more reactants and a carrier gas into an etching chamber comprising the compound, wherein each of the metals can be etched by a plasma of at least one of said reactants,
stopping the injection of at least one of the two or more reactants, and responsively causing a decrease of the concentration of at least one reactant of the two or more reactants, and
igniting a plasma within the etching chamber for a time period such that the plasma is present during the decrease of the concentration.

19. The non-transitory computer-readable medium according to claim 18, wherein the carrier gas is different from any of the reactants and is not reactive toward the compound.

20. The non-transitory computer-readable medium according to claim 18, wherein the carrier gas is one of the two or more reactants and is the primary reactant responsible to etch the element of the compound with the slowest etch rate in presence of its primary reactant.
